(19) United States
(12) Patent Application Publication
(10) Pub. No.: US 2024/0213432 A1
(43) Pub. Date: Jun. 27, 2024

(54) LIGHT EMITTING CHIP AND PRODUCING METHOD THEREOF, AND LIGHT EMITTING APPARATUS

(71) Applicants: BOE MLED Technology Co., Ltd., Beijing (CN); BOE Technology Group Co., Ltd., Beijing (CN)

(72) Inventors: Shanwei YANG, Beijing (CN); Junjie MA, Beijing (CN); Yuanda LU, Beijing (CN); Zhijun XIONG, Beijing (CN); Linxia QI, Beijing (CN); Jiawei ZHAO, Beijing (CN); Yuanhao SUN, Beijing (CN)

(21) Appl. No.: 17/918,214

(22) PCT Filed: Oct. 29, 2021
(86) PCT No.: PCT/CN2021/127403

§ 371 Date: Oct. 11, 2022

(51) Int. Cl. H01L 33/64; H01L 25/075; H01L 33/38; H01L 33/62

(52) U.S. Cl. CPC H01L 33/642; H01L 25/0753; H01L 33/382; H01L 33/62; H01L 33/641; H01L 2933/0016; H01L 2933/0075

(57) ABSTRACT

The present disclosure provides a light emitting chip and a producing method thereof, and a light emitting apparatus. The light emitting chip includes a patterned substrate; a light emitting unit, wherein the light emitting unit includes an electron injection layer, a luminescent layer and a hole injection layer; a first electrode, wherein the first electrode is connected to the electron injection layer; a second electrode, wherein the second electrode is connected to the hole injection layer; a first passivation layer, wherein the first passivation layer partially covers the light emitting unit, the first electrode and the second electrode, the first passivation layer includes a first opening, and the light emitting unit partially exposes from the first opening; and a heat dissipating layer, wherein the heat dissipating layer covers the first passivation layer, and a part of the light emitting unit exposing from the first passivation layer.

### TECHNICAL FIELD

The present disclosure relates to the technical field of displaying and, more particularly, to a light emitting chip and a producing method thereof, and a light emitting apparatus.

### BACKGROUND

Mini-LED light emitting chips and Micro-LED light emitting chips are the focus of the development of the LED (Light Emitting Diode) technique in recent years. Mini/Micro-LED light emitting chips may be extensively applied to fields such as the backlight sources of liquid-crystal displays, Mini/Micro RGB display screens and small-spacing display screens.

In order to realize the mass production of Mini/Micro-LED products at a low cost and a low power consumption, design solutions of high-voltage chips such as 6V, 9V and 12V are being gradually introduced into Mini/Micro-LED light emitting chips, to form the conventional high-voltage Mini/Micro-LED light emitting chips.

However, the interior of the conventional high-voltage Mini/Micro-LED light emitting chips is divided into a plurality of small light emitting units (cells), and because each of the small light emitting units has a low area, the high-voltage Mini/Micro-LED light emitting chips have few heat-dissipation paths, and a poor heat-dissipation performance.

### SUMMARY

The present disclosure provides a light emitting chip, wherein the light emitting chip includes:
a patterned substrate;
a light emitting unit, wherein the light emitting unit includes an electron injection layer, a luminescent layer and a hole injection layer that are sequentially formed on the patterned substrate in stack;
a first electrode and a second electrode, wherein the first electrode is connected to the electron injection layer, and the second electrode is connected to the hole injection layer;
a first passivation layer, wherein the first passivation layer partially covers the light emitting unit, the first electrode and the second electrode, the first passivation layer includes a first opening, and the light emitting unit partially exposes from the first opening; and
a heat dissipating layer, wherein the heat dissipating layer covers the first passivation layer, and a part of the light emitting unit exposing from the first passivation layer.

Optionally, the light emitting unit further includes a current expanding layer formed on the hole injection layer, and the current expanding layer partially exposes from the first opening of the first passivation layer.

Optionally, the light emitting chip further includes:
an optical-adjustment layer, wherein the optical-adjustment layer at least partially covers the heat dissipating layer; and
bonding pads, wherein the bonding pads include a first bonding pad and a second bonding pad, the first bonding pad is connected to the first electrode exposing from the first passivation layer by via holes in the optical-adjustment layer and the heat dissipating layer, the second bonding pad is connected to the second electrode exposing from the first passivation layer by via holes in the optical-adjustment layer and the heat dissipating layer, and the heat dissipating layer is insulative.

Optionally, the light emitting chip further includes:
a heat dissipating end, wherein the heat dissipating end is disposed on the optical-adjustment layer, the optical-adjustment layer is provided with a second opening exposing the heat dissipating layer, and the heat dissipating end is connected to the heat dissipating layer by the second opening.

Optionally, an orthographic projection of the first opening on the patterned substrate and an orthographic projection of the heat dissipating end on the patterned substrate intersect or overlap.

Optionally, in a stacking direction of the light emitting chip, a height of a part of the heat dissipating end that exceeds the optical-adjustment layer is less than or equal to a height of a part of the bonding pads that exceeds the optical-adjustment layer.

Optionally, the heat dissipating end has a fin structure.

Optionally, the heat dissipating end is embedded into the second opening.

Optionally, the heat dissipating end covers an edge of the optical-adjustment layer close to the second opening.

Optionally, a material of the heat dissipating end is at least one of aluminium nitride and silicon carbide, and a material of the heat dissipating layer is at least one of aluminium nitride and silicon carbide.

Optionally, the light emitting chip includes at least three light emitting units that are arranged in a target direction and are connected in series by bridge electrodes, the first electrode and the second electrode are individually connected to the light emitting units close to two ends of the light emitting chip, and an orthographic projection of the heat dissipating end on the patterned substrate and an orthographic projection on the patterned substrate of the light emitting unit between the light emitting units close to the two ends of the light emitting chip intersect or overlap.

Optionally, the first passivation layer includes:
a patterned first passivation sublayer, wherein the first electrode is connected to the electron injection layer of the corresponding light emitting unit by a via hole in the first passivation sublayer, the second electrode is connected to the hole injection layer of the corresponding light emitting unit by the via hole in the first passivation sublayer, and each of the bridge electrodes is disposed on the first passivation sublayer, and connects two instances of the light emitting units by the via hole in the first passivation sublayer; and
a patterned second passivation sublayer, wherein the patterned second passivation sublayer covers the bridge electrodes, and the first opening is disposed in the second passivation sublayer.

Optionally, the light emitting chip further includes:
a second passivation layer, wherein the second passivation layer is disposed on side walls of via holes of the optical-adjustment layer and the heat dissipating layer where the bonding pads are located.

Optionally, in a stacking direction of the light emitting chip, a minimum thickness of the heat dissipating layer is greater than or equal to 1.2 μm, and less than or equal to 4 micrometers.

The present disclosure further provides a method for producing a light emitting chip, used to produce the light emitting chip stated above, wherein the method includes:
forming sequentially an electron injection layer, a luminescent layer and a hole injection layer in stack on a patterned substrate, to obtain a light emitting unit;
patterning to form a first passivation layer, a first electrode and a second electrode, wherein the first electrode is connected to the electron injection layer, the second electrode is connected to the hole injection layer, the first passivation layer partially covers the light emitting unit, the first electrode and the second electrode, the first passivation layer includes a first opening, and the light emitting unit partially exposes from the first opening; and
forming a heat dissipating layer, wherein the heat dissipating layer covers the first passivation layer, and a part of the light emitting unit exposing from the first passivation layer.

Optionally, after the step of forming the heat dissipating layer, the method further includes:
forming an optical-adjustment layer, wherein the optical-adjustment layer is provided with a second opening exposing the heat dissipating layer; and
forming a heat dissipating end on the heat dissipating layer exposing from the second opening.

Optionally, after the step of forming the heat dissipating layer, the method further includes:
forming an optical-adjustment layer, wherein the optical-adjustment layer is provided with a second opening exposing the heat dissipating layer, and the heat dissipating layer includes a part embedded into the second opening; and
forming the heat dissipating end on the optical-adjustment layer, wherein the heat dissipating end covers an edge of the optical-adjustment layer close to the second opening, and the heat dissipating end is connected to the part of the heat dissipating layer that is embedded into the second opening.

Optionally, after the step of forming the heat dissipating end on the optical-adjustment layer, the method further includes:
performing laser etching to the heat dissipating end, to form a fin structure on the heat dissipating end.

The present disclosure further provides a light emitting apparatus, wherein the light emitting apparatus includes the light emitting chip stated above.

Optionally, the light emitting apparatus further includes a driving base plate, the driving base plate includes a first connecting end and a second connecting end, the light emitting chip includes a first bonding pad and a second bonding pad, the first bonding pad is connected to the first connecting end, the second bonding pad is connected to the second connecting end, the driving base plate further includes a closing component located between the first connecting end and the second connecting end, the closing component is for closing a film layer exposing from between the first connecting end and the second connecting end on the driving base plate, the light emitting chip includes a heat dissipating end, and the heat dissipating end abuts the closing component.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly described below. Apparently, the figures that are described below are embodiments of the present disclosure, and a person skilled in the art may obtain other figures according to these figures without paying creative work.

FIG. 1 shows a schematic diagram of the bridging of the light emitting units in a conventional light emitting chip:

FIG. 2 shows a schematic diagram of an overhead light emitting unit in a conventional light emitting chip:

FIG. 3 shows a schematic diagram of an overhead light emitting unit in another conventional light emitting chip:

FIG. 4 shows a schematic cross-sectional view of a light emitting chip according to an embodiment of the present disclosure:

FIG. 5 shows a schematic cross-sectional view of another light emitting chip according to an embodiment of the present disclosure:

FIG. 6 shows a schematic cross-sectional view of yet another light emitting chip according to an embodiment of the present disclosure:

FIG. 7 shows schematic top views of several arrangement modes of the light emitting units according to an embodiment of the present disclosure:

FIG. 8 shows a flow chart of the steps of the method for producing a light emitting chip according to another embodiment of the present disclosure:

FIGS. 9-18 show schematic cross-sectional views of the chip in the flow of the method for producing a light emitting chip according to an embodiment of the present disclosure:

FIGS. 19-23 show schematic flow charts of the treatments after the light emitting chip has been produced according to an embodiment of the present disclosure:

FIG. 24 shows a schematic cross-sectional view of a light emitting apparatus according to an embodiment of the present disclosure; and

FIG. 25 shows a schematic cross-sectional view of another light emitting apparatus according to an embodiment of the present disclosure.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

Unless defined otherwise, the technical terminologies or scientific terminologies used in the present disclosure should have the meanings generally understood by a person skilled in the art of the present disclosure. The words used herein such as “first” and “second” do not indicate any sequence, quantity or priority, but are merely intended to distinguish different components. Likewise, the words such as “a”, “an” or “the” do not indicate quantitative limitations, but indicate the existence of at least one instance. The words such as “comprise” or “include” mean that the element or article preceding the word encompasses the elements or articles and the equivalents thereof that are listed subsequent to the word, but do not exclude other elements or articles. The words such as “connect” or “couple” are not limited to physical or mechanical connections, but may include electric connections, regardless of direct connections or indirect connections. The orientation terms such as “upper”, “lower”, “left” and “right” are merely intended to indicate relative positions on the basis of the figures, and if the absolute position of the described item has changed, the relative positions might also be correspondingly changed.

With the development of the technique of displaying, people are having increasingly more demands on products of 4K, 8K, and so on, based on Mini/Micro LED, such as high-performance television sets (TV). Monitors (MNT), notebook computers (NB) and full-color display screens. In practical applications, there have already been Mini/Micro LED backlight and display products based on different packaging forms such as POG/POB (Package OnGlass/Board), COB (Chip On Board) and COG (Chip On Glass).

Mini/Micro LED chips, as the core light emitting device of Mini/Micro-LED products, are having increasingly stricter requirements on the performance thereof. However, the conventional Mini/Micro LED chips still have a high heat conversion rate. Taking the high-voltage Mini LED chips used for backlight as an example, up to approximately 34% of their electric power is converted into heat by non-recombination radiation. Moreover, regarding the RGBMini LED chips of the sizes of 4×8 mil and 3×6 mil used for small-spacing display screens, the proportion of the heat converted by non-recombination radiation may even be up to approximately 70%. Therefore, it is of vital importance for high-voltage Mini/Micro LED chips to have an excellent heat-dissipation performance.

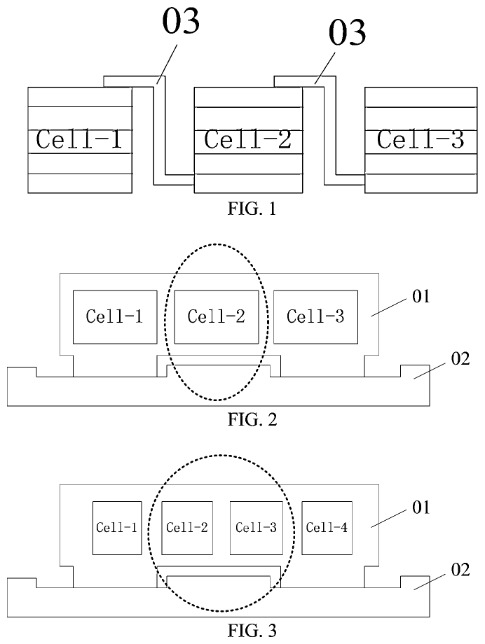

However, as different from traditional single-particle low-voltage Mini/Micro LED chips, the conventional high-voltage Mini/Micro LED chips include two or more small light emitting units (cells) at the interior. As shown by the cross-sectional view of the chip in FIG. 1, the cells are connected together by bridge electrodes 03. Because each of the cells inside the chip has a low area, the Mini/Micro LED chips have few heat-dissipation paths, and a poor heat-dissipation performance.

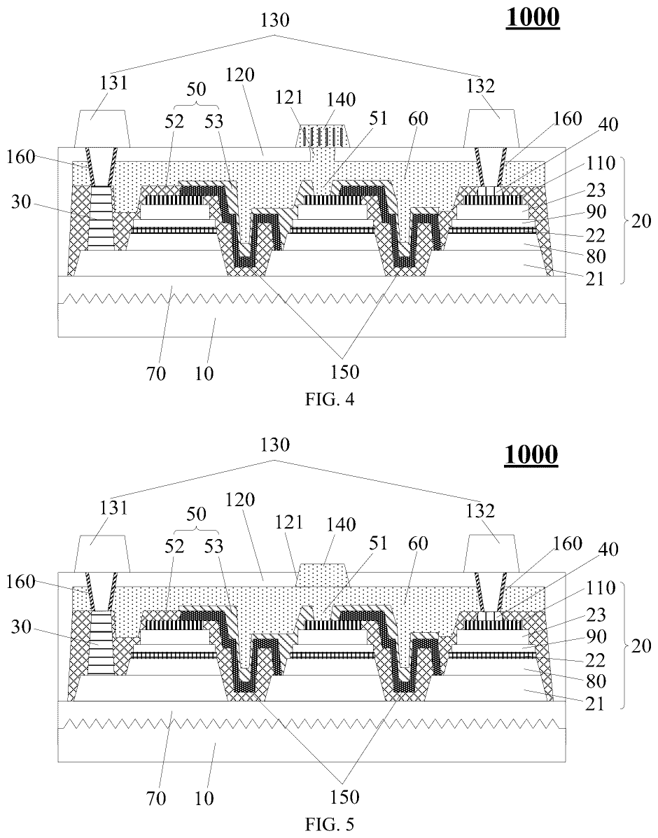

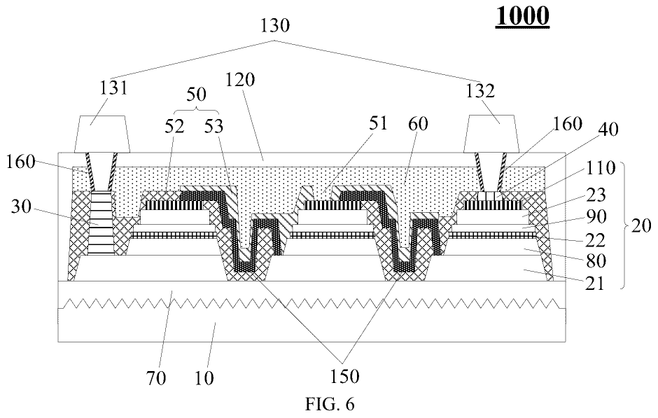

What is worse is that, regarding, for example, the cell layout mode shown in FIG. 2 (wherein the cells are connected in series in the form of 1×3), and the cell layout mode shown in FIG. 3 (wherein the cells are connected in series in the form of 1×4), some of the cells are completely overhead over the driving base plate 02. After the Mini/Micro LED chip 01 has been welded to the driving base plate 02, the overhead cell does not contact the driving base plate 02, and the overhead cell cannot be supported, whereby the Mini/Micro LED chip does not only have a poor heat-dissipation performance, but also has a very poor mechanical strength.

A poor heat-dissipation performance and a poor mechanical performance are fatal problems for Mini/Micro LED backlight and display products. If the Mini/Micro LED chip has a poor heat-dissipation performance, the heat generated in the operation of the Mini/Micro LED chip accumulates in its interior, which results in the increasing of the junction temperature of the Mini/Micro LED chip. Further, the increasing of the junction temperature further results in problems such as decreasing of the luminous efficiency of the Mini/Micro LED chip, red shift of the luminous color, decreasing of the forward voltage and life shortening. If the Mini/Micro LED chip has a poor mechanical performance, the Mini/Micro LED chip easily cracks, which results in failure of the Mini/Micro LED chip.

Based on the prior art described above, a light emitting chip and a producing method thereof, and a light emitting apparatus according to the embodiments of the present disclosure are provided.

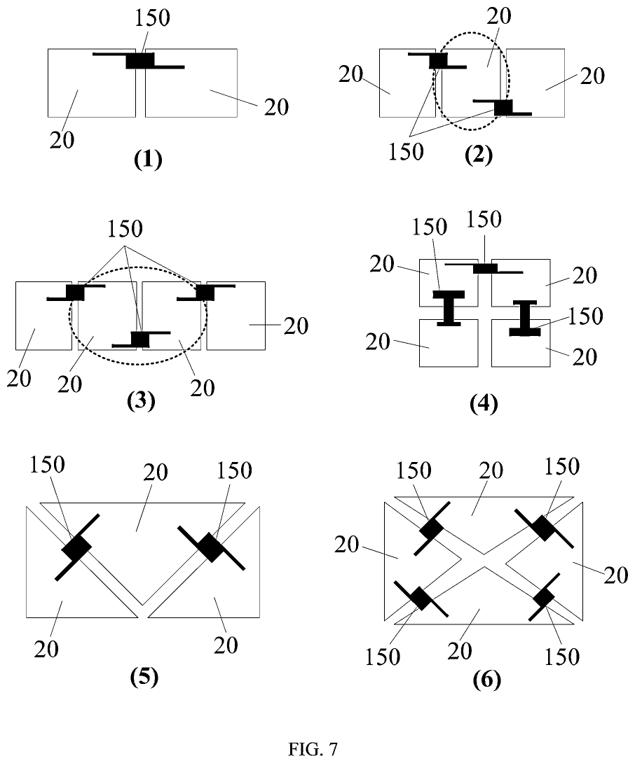

FIGS. 4, 5 and 6 individually show schematic cross-sectional views of three light emitting chips 1000 according to embodiments of the present disclosure. Referring to FIGS. 4, 5 and 6, the light emitting chip 1000 includes:
a patterned substrate 10;
a light emitting unit 20, wherein the light emitting unit 20 includes an electron injection layer 21, a luminescent layer 22 and a hole injection layer 23 that are sequentially formed on the patterned substrate 10 in stack;
a first electrode 30 and a second electrode 40, wherein the first electrode 30 is
connected to the electron injection layer 21, and the second electrode 40 is connected to the hole injection layer 23;
a first passivation layer 50, wherein the first passivation layer 50 partially covers the light emitting unit 20, the first electrode 30 and the second electrode 40, the first passivation layer 50 includes a first opening 51, and the light emitting unit 20 partially exposes from the first opening 51; and
a heat dissipating layer 60, wherein the heat dissipating layer 60 covers the first passivation layer 50, and the part of the light emitting unit 20 exposing from the first passivation layer 50.

Optionally, the patterned substrate 10 may be made from sapphire (Al₂O₃), and has patterned structures of a spacing of 1-2 μm. The patterned structures may be used to reduce the defect density of the sapphire substrate, to improve the crystal quality, thereby increasing the luminous efficiency of the light emitting chip 1000.

Referring to FIGS. 4, 5 and 6, in some embodiments, the light emitting chip 1000 may particularly further include a buffer layer 70 formed on the patterned substrate 10. The buffer layer 70 generally may be produced by using a GaN material, and may have a thickness of approximately 2 μm. The buffer layer 70 may be used to ameliorate the mismatching between the lattice constants of the sapphire substrate and the GaN material.

The electron injection layer 21 may be used to provide electrons. Optionally, the electron injection layer 21 may be produced by using a Si-doped GaN, may serve as the N area of the light emitting unit 20, and may have a thickness of approximately 360 Å.

Referring to FIGS. 4, 5 and 6, in some embodiments, the light emitting chip 1000 may particularly further include a superlattice layer 80 formed on the electron injection layer 21. In an alternative embodiment, the superlattice layer 80 may include totally 6 potential barrier/potential well pairs formed by InGaN of 2 nm and GaN of 25 nm, may have a total thickness of 1600 Å, and is used to improve the epitaxy quality.

The luminescent layer 22 is the light emitting area of the light emitting chip 1000, and may serve to restrain the charge carriers. In some embodiments, the luminescent layer 22 may particularly be a multi-quantum well luminescent layer, may include totally 9) potential barrier/potential well pairs formed by InGaN of 3 nm and GaN of 12 nm, may have a total thickness of 1300 Å.

Referring to FIGS. 4, 5 and 6, in some embodiments, the light emitting chip 1000 may particularly further include an electron blocking layer 90 formed on the luminescent layer 22. The electron blocking layer 90 may be used to block the electrons from leaking to the P area of the light emitting unit 20, to increase the recombination rate of the electrons and the holes in the luminescence recombination area. Optionally, the electron blocking layer 90 may be produced by using InGaN, and may have a thickness of 230 Å.

The hole injection layer 23 may be used to provide holes. Optionally, the hole injection layer 23 may be produced by using an Mg-doped GaN, may serve as the P area of the light emitting unit 20, and may have a thickness of approximately 3500 Å.

The first electrode 30 may be connected to the electron injection layer 21, thereby serving as the N electrode of the light emitting chip 1000. The second electrode 40 may be connected to the hole injection layer 23, thereby serving as the P electrode of the light emitting chip 1000.

The first passivation layer 50 may be used to isolate the other positions than the switched-on position inside the light emitting chip 1000, to prevent short circuiting of the light emitting chip 1000. The first passivation layer 50 is provided with the first opening 51, the light emitting unit 20 partially exposes from the first opening 51, and the first opening 51 may leave a heat dissipating channel for the light emitting unit 20.

Referring to FIGS. 4, 5 and 6, optionally, the light emitting unit 20 further includes a current expanding layer 110 formed on the hole injection layer 23, and the current expanding layer 110 partially exposes from the first opening 51 of the first passivation layer 50. The current expanding layer 110 of the light emitting unit 20 partially exposes the first passivation layer 50, whereby the light emitting unit 20 and the heat dissipating layer 60 may directly contact, to form the heat dissipating channel, which facilitates the discharging of the heat of the light emitting unit 20.

The heat dissipating layer 60 may be used to dissipate the heat inside the light emitting chip 1000, to increase the speed of the transfer of the heat of the positions of the PN junctions to the external.

In the embodiments of the present disclosure, the heat dissipating layer 60 may be introduced into the light emitting chip 1000, which increases the heat dissipating channels of the heat inside the light emitting chip 1000, thereby quickly discharging the temperature inside the light emitting chip 1000, to improve the heat-dissipation performance of the light emitting chip 1000, and reduce the overall temperature of the modules. Meanwhile, the heat dissipating layer 60 may serve as a high-strength packing layer inside the light emitting chip 1000, which may increase the mechanical strength of the light emitting chip 1000.

Referring to FIGS. 4, 5 and 6, optionally, the light emitting chip 1000 may further include:
an optical-adjustment layer 120, wherein the optical-adjustment layer 120 at least partially covers the heat dissipating layer 60; and
bonding pads 130, wherein the bonding pads 130 include a first bonding pad 131 and a second bonding pad 132, the first bonding pad 131 is connected to the first electrode 30 exposing from the first passivation layer 50 by via holes in the optical-adjustment layer 120 and the heat dissipating layer 60, the second bonding pad 132 is connected to the second electrode 40 exposing from the first passivation layer 50 by via holes in the optical-adjustment layer 120 and the heat dissipating layer 60, and the heat dissipating layer 60 is insulative.

The optical-adjustment layer 120 may be used to enable the lights exiting from the luminescent layer 22 to be more reflected to the sapphire substrate, thereby increasing the extraction rate of the lights. In some embodiments, the optical-adjustment layer 120 may include the structure of a distributed Bragg reflector. Optionally, the structure of a distributed Bragg reflector may particularly be a structure in which TiOₓ film layers and SiOₓ film layers are stacked alternately, have totally 48 layers, and may have a total thickness of approximately 3.5 μm.

The bonding pads 130 may be used to connect the electrodes of the light emitting chip 1000 to the corresponding signal connecting terminals in the driving base plate, wherein the first bonding pad 131 is connected to the N electrode of the light emitting chip 1000, and the second bonding pad 132 is connected to the P electrode of the light emitting chip 1000. Both of the optical-adjustment layer 120 and the heat dissipating layer 60 are provided with via holes, and the bonding pads may be connected to the corresponding electrodes by the via holes. Because both of the bonding pads and the corresponding electrodes are required to be electrically switched on, the heat dissipating layer 60 is required to be insulative, which may prevent short circuiting of the light emitting chip 1000.

Particularly, each of the bonding pads may particularly include a bonding-pad connector and a bonding-pad body. The bonding-pad connector is the part of the bonding pad that is embedded into the via holes in the optical-adjustment layer 120 and the heat dissipating layer 60. The bonding-pad body is located on the side of the bonding-pad connector that is away from the patterned substrate 10. The bonding-pad body covers the edge of the optical-adjustment layer 120 close to the via hole.

Referring to FIGS. 4, 5 and 6, optionally, the light emitting chip 1000 further includes:
a heat dissipating end 140, wherein the heat dissipating end 140 is disposed on the optical-adjustment layer 120, the optical-adjustment layer 120 is provided with a second opening 121 exposing the heat dissipating layer 60, and the heat dissipating end 140 is connected to the heat dissipating layer 60 by the second opening 121.

The heat dissipating end 140 protrudes out of the light emitting chip 1000, and may be used to increase the heat dissipating channels of the light emitting chip 1000, to more quickly diffuse the heat inside the light emitting chip 1000 to the exterior of the light emitting chip 1000, which further improves the heat-dissipation performance of the light emitting chip 1000.

Optionally, in some embodiments, the orthographic projection of the first opening 51 on the patterned substrate 10 and the orthographic projection of the heat dissipating end 140 on the patterned substrate 10 intersect or overlap.

In the stacking direction of the light emitting chip 1000, the first opening 51 and the heat dissipating end 140 intersect or overlap: in other words, the heat dissipating end 140 may be disposed over the heat dissipating channel of the light emitting unit 20. That may shorten the path of the heat transfer of the light emitting unit 20, whereby the heat of the light emitting unit 20 may be dissipated to the exterior of the light emitting chip 1000 as soon as possible.

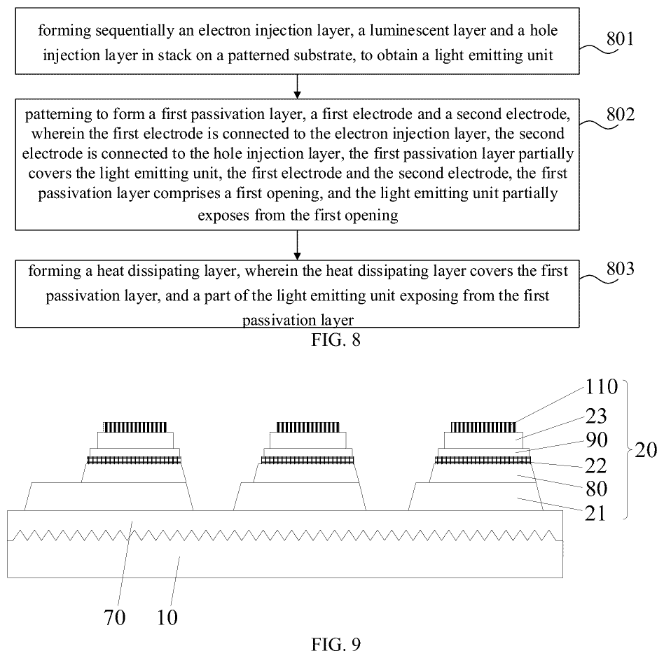

In some embodiments, referring to FIGS. 4 and 5, optionally, in the stacking direction of the light emitting chip 1000, the height of a part of the heat dissipating end 140 that exceeds the optical-adjustment layer 120 is less than or equal to the height of a part of the bonding pads 130 that exceeds the optical-adjustment layer 120.

Because the light emitting chip 1000 may be welded to the driving base plate via the bonding pads 130, the height of the heat dissipating end 140 should not exceed the height of the part of the bonding pads 130 that exceeds the optical-adjustment layer 120; in other words, the height of the heat dissipating end 140 should not exceed the height of the bonding-pad body, which may ensure the normal welding between the bonding pads 130 and the driving base plate.

In some embodiments, referring to FIG. 4, optionally, the heat dissipating end 140 has a fin structure. That may increase the heat dissipating area of the heat dissipating end 140.

In an alternative implementation, referring to FIG. 5, the heat dissipating end 140 may be embedded into the second opening 121.

In another alternative implementation, referring to FIG. 4, the heat dissipating end 140 may cover the edge of the optical-adjustment layer 120 close to the second opening 121.

As compared with the second implementation, in the first implementation, when the heat dissipating end 140 and the heat dissipating layer 60 employ the same material, the heat dissipating end 140 and the heat dissipating layer 60 require lesser process steps, and the process is simpler.

As compared with the first implementation, in the second implementation, the optical-adjustment layer 120 has a higher deployment area, which may enable the light emitting chip 1000 to have a higher light extraction yield.

Optionally, the light emitting chip 1000 includes at least three light emitting units 20 that are arranged in a target direction and are connected in series by bridge electrodes 150, the first electrode 30 and the second electrode 40 are individually connected to the light emitting units 20 close to the two ends of the light emitting chip 1000, and the orthographic projection of the heat dissipating end 140 on the patterned substrate 10 and the orthographic projection on the patterned substrate 10 of at least one light emitting unit between the light emitting units close to the two ends of the light emitting chip 1000 intersect or overlap.

The target direction is a preset direction, and may be preset according to demands in practical applications. All of the light emitting units 20 that are connected in series are disposed in the target direction, and the first electrode 30 and the second electrode 40 are connected to the light emitting units 20 at the head position and the tail position (or the tail position and the head position) of the series connection respectively. In the prior art, when the light emitting chip 1000 is welded to the driving base plate, the first bonding pad 131 may support the light emitting unit 20) connected to the first electrode 30, and the second bonding pad 132 may support the light emitting unit 20 connected to the second electrode 40. However, the light emitting unit 20 between the light emitting units 20 at the head position and the tail position is overhead over the driving base plate, and the driving base plate cannot support the light emitting unit 20 in the middle position. However, in the embodiments of the present disclosure, the orthographic projection of the heat dissipating end 140 on the patterned substrate 10 and the orthographic projection on the patterned substrate 10 of the light emitting unit 20 between the light emitting units 20 close to the two ends of the light emitting chip 1000 intersect or overlap: in other words, in the stacking direction of the light emitting chip 1000, the heat dissipating end 140 and the light emitting chip 1000 in the middle position intersect or overlap. Accordingly, the heat dissipating end 140, by height configuration, may abut the driving base plate, and support the light emitting unit 20 in the middle position, which increases the mechanical strength of the light emitting chips 1000.

Certainly, regarding the light emitting chips 1000 including one or two light emitting units 20, the heat dissipating end 140 may also be disposed on the light emitting chip 1000.

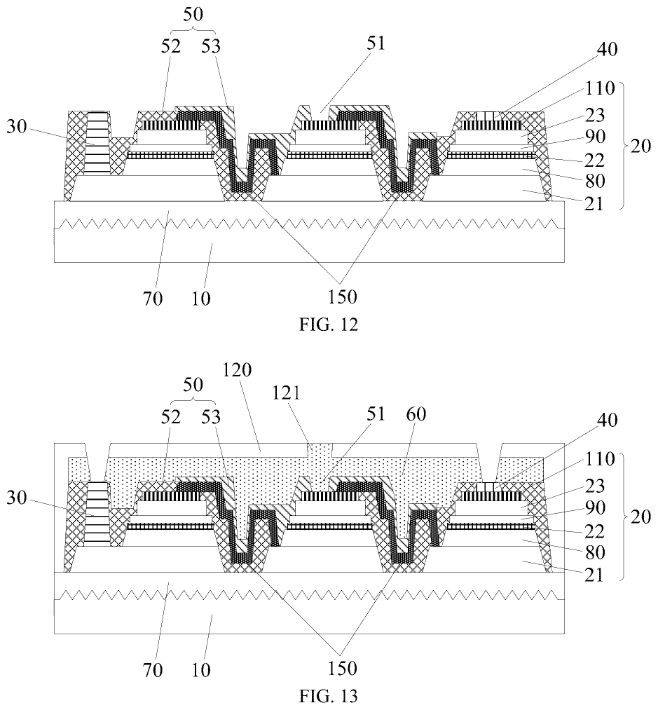

Referring to FIG. 7. FIG. 7 schematically shows top views of the arrangement of several light emitting units 20. In some of the light emitting chips, all of the orthographic projections of the light emitting units 20 on the patterned substrate 10 intersect or overlap with the orthographic projection of the bonding pads 130 on the patterned substrate 10, and such light emitting chips are light emitting chips having no overhead light emitting unit 20. After the light emitting chips having no overhead light emitting unit 20 have been assembled with the driving base plate, there is no light emitting unit 20 that is completely overhead over the driving base plate. It may be understood that, regarding the light emitting chips 1000 having no overhead light emitting unit, for example, the (1), (4), (5) and (6) in FIG. 7, the heat dissipating end 140 may not be disposed, and the light emitting chip 1000 may still maintain a good level of the mechanical performance. Regarding the arrangement modes of the light emitting units shown in (2) and (3) in FIG. 7, the heat dissipating end 140 may be disposed, wherein the light emitting units 20 circled by the dotted lines in (2) and (3) in FIG. 7 are the light emitting units that are overhead over the driving base plate.

In an embodiment of the present disclosure, further optionally, in the stacking direction of the light emitting chip 1000, the minimum thickness of the heat dissipating layer 60 is greater than or equal to 1.2 μm, and less than or equal to 4 micrometers. The heat dissipating layer 60 that satisfies such a thickness range, while serving to dissipate heat, may also serve as a high-strength packing layer over the bridge electrodes, which may increase the mechanical strength at the bridging positions.

Referring to FIGS. 4, 5 and 6, further optionally, the first passivation layer 50 may include:
a patterned first passivation sublayer 52, wherein the first electrode 30 is connected to the electron injection layer 21 of the corresponding light emitting unit 20 by a via hole in the first passivation sublayer 52, the second electrode 40 is connected to the hole injection layer 23 of the corresponding light emitting unit 20 by the via hole in the first passivation sublayer 52, and each of the bridge electrodes 150 is disposed on the first passivation sublayer 52, and connects two of the light emitting units 20 by the via hole in the first passivation sublayer 52; and
a patterned second passivation sublayer 53, wherein the patterned second passivation sublayer 53 covers the bridge electrodes 150, and the first opening 51 is disposed in the second passivation sublayer 53.

Referring to FIGS. 4, 5 and 6, the bridge electrodes 150 are disposed on the first passivation sublayer 52, and the first passivation sublayer 52 may be used to isolate the bridge electrodes 150 from the conductive film layers in the light emitting units 20, and merely leave the positions on the light emitting units 20 that are required to be switched on with the electrodes. The second passivation sublayer 53 may be used to isolate the heat dissipating layer 60 from the bridge electrodes 150, to prevent short circuiting of the light emitting chip 1000.

The thickness of the second passivation sublayer 53 may be approximately 1000-2000 Å, and the thickness of the entire first passivation layer 50 may be approximately 4000-4500 Å.

Referring to FIGS. 4, 5 and 6, optionally, the light emitting chip 1000 may further include:
a second passivation layer 160, wherein the second passivation layer 160 is disposed on the side walls of via holes of the optical-adjustment layer 120 and the heat dissipating layer 60 where the bonding pads 130 are located.

In some embodiments, the second passivation layer 160 may be disposed on the side walls of via holes of the optical-adjustment layer 120 and the heat dissipating layer 60 where the bonding pads 130 are located. The second passivation layer 160 may be used to isolate the bonding-pad connector and the via holes, whereby the heat dissipating layer 60 does not directly contact the bonding pads 130, the first electrode 30 and the second electrode 40, which may prevent electric leakage of the light emitting unit 20 via the heat dissipating layer 60, to prevent short circuiting of the light emitting chip 1000.

Optionally, practical applications, the material of the heat dissipating end 140 may be at least one of aluminium nitride (AlN) and silicon carbide (SiC), and the material of the heat dissipating layer 60 may be at least one of aluminium nitride and silicon carbide.

AlN has an extremely high thermal conductivity of 240W/(M·K), and a coefficient of thermal expansion of 3.3-5.0 (×10⁻⁶/° C.), which matches with the coefficient of thermal expansion of the light emitting chip 1000 very much. Moreover. AlN has a melting point of 2470° C., is very high-temperature resistant, and has an excellent insulativity, an extremely high strength and an extremely high corrosion resistance.

Although AlN has an excellent insulativity, because it contacts nearly all of the film layers that are electrically switched on inside the light emitting chip 1000, in order to prevent electric leakage of the light emitting chip 1000, passivation layers may be added under the AlN thermal conducting layer and at the periphery of the bonding pads, to enhance the electric performance of the light emitting chip 1000. The added passivation layer further enables that not only AlN may serve as the heat dissipating film layer, but also materials whose insulativity is inferior to that of AlN such as SiC and BeO may also be used as a heat dissipating film layer, and be added into the light emitting chip 1000 to improve the heat-dissipation performance of the chip. If SiC is used, then it is required to produce a relatively compact passivation layer, to reduce the risk in short circuiting of the light emitting chip 1000. However. BeO may be used in the product of the light emitting chip 1000 as described in the method described above.

Besides the illustrative materials and thicknesses of the film layers described above, the materials and the thicknesses of other film layers will be illustratively described below.

All of the passivation layers may be produced by using SiO₂. All of the bridge electrodes 150, the first electrode 30 and the second electrode 40 may be of a tandem metal structure formed by Ti/Al/Ti/Ni/Ti/Al/Ti/Pt/Au. The thicknesses of the first electrode 30 and the second electrode 40 may be approximately 1.47 μm, and the thicknesses of the metal layers are approximately 5 nm/12 nm/88 nm/42 nm/316 nm/103 nm/627 nm/97 nm/182 nm respectively. The thicknesses of the bridge electrodes 150 may be approximately 1.45 μm, and the thicknesses of the metal layers are approximately 3 nm/5 nm/86 nm/42 nm/312 nm/98 nm/623 nm/93 nm/189 nm respectively. The current expanding layer 110 may employ an ITO material, and may have a thickness of approximately 1000 Å. The bonding-pad connector may be of a tandem metal structure formed by Ti/Al/Ti/Pt—Au alloy/Ni/Pt—Au alloy, and the thicknesses of the metal layers are 94 nm/206 nm/92 nm/63 nm/328 nm/58 nm respectively. The bonding-pad body may employ a Sn—Ag—Cu alloy, the material proportion of which may be Sn-96.5%. Ag-3% and Cu-0.5%, and the thickness of the bonding-pad body may be 8±0.8 μm.

In the prior art, the mode of heat dissipation of changing the base-plate material (for example, the base plate employs a ceramic material having a good heat-dissipation performance) or the LED-support material is merely suitable for Mini/Micro-LED products in the packaging form of POG, and is not suitable for Mini/Micro-LED products in the packaging forms of COB and COG. That is mainly because the materials of the base plates in the packaging forms of COB and COG are constant, wherein COB uses a PCB or FPC base plate, and COG uses a glass base plate, the heat-dissipation performance has already tended to saturation, with substantially no possibility of improvement, and there is no LED support. Currently, the heat dissipation of COB and COG is mainly by means of adding a temperature sensor, and, after the Mini/Micro-LED panel has reached the preset temperature, by forcibly reducing the current, reducing the heat while compromising the brightness and the optical effect. As compared with the prior art, the light emitting chip according to the embodiments of the present disclosure may reach a very good effect of heat dissipation without adding any external device and without compromising the optical effect.

In the embodiments of the present disclosure, the heat dissipating layer 60 may be introduced into the light emitting chip 1000, and the heat dissipating end 140 may be added outside the light emitting chip 1000. The heat dissipating layer 60 may dissipate the heat inside the light emitting chip 1000 by means of thermal conduction, and the heat dissipating layer 60 may increase the mechanical strength of the light emitting unit 20 at the bridging positions. The heat dissipating end 140 may conduct the heat inside the light emitting chip 1000 to the exterior of the light emitting chip 1000 by means of thermal radiation, and the heat dissipating end 140 may serve to support the overhead light emitting unit. Accordingly, both of the heat-dissipation performance and the mechanical performance of the light emitting chip 1000 are improved.

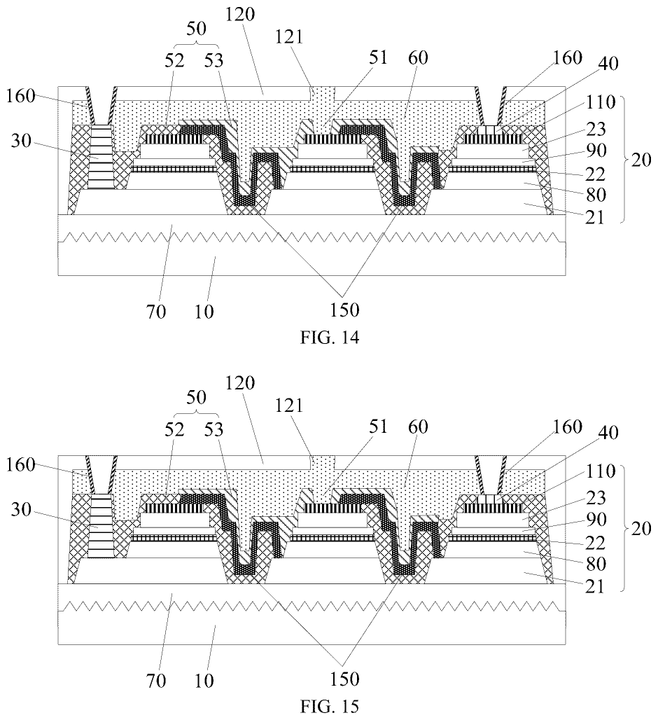

Referring to FIG. 8. FIG. 8 shows a flow chart of the steps of the method for producing a light emitting chip 1000 according to an embodiment of the present disclosure. The producing method is used to produce the light emitting chip 1000 stated above. The producing method includes the following steps:

Step 801: forming sequentially an electron injection layer, a luminescent layer and a hole injection layer in stack on a patterned substrate, to obtain a light emitting unit.

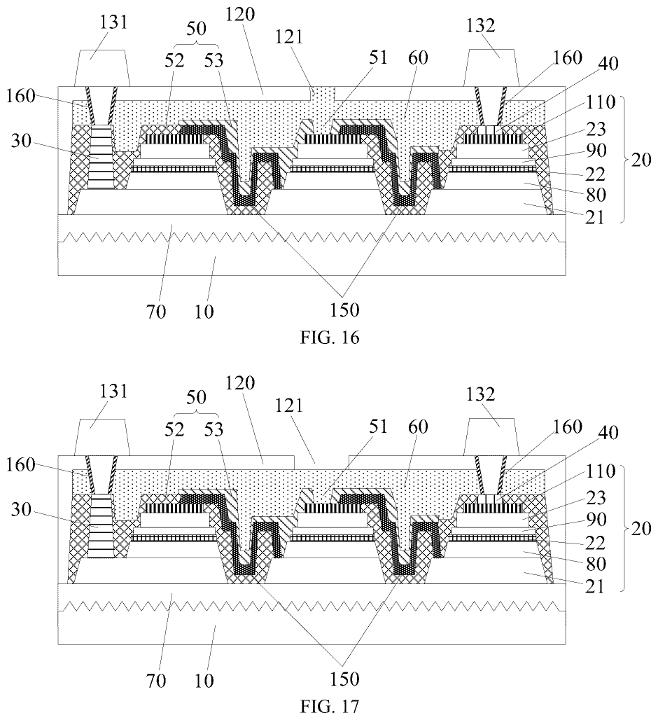

This step may include, firstly, sequentially growing the buffer layer 70, the electron injection layer 21, the superlattice layer 80, the luminescent layer 22, the electron blocking layer 90, the hole injection layer 23 and the current expanding layer 110 on a PSS substrate by using an MOCVD (Metalorganic Chemical Vapor Deposition) process, and subsequently etching the via holes and isolating grooves at positions where the thickness is relatively large by using processes such as lithography and etching, to obtain the light emitting units 20, as shown in FIG. 9.

Step 802: patterning to form a first passivation layer, a first electrode and a second electrode, wherein the first electrode is connected to the electron injection layer, the second electrode is connected to the hole injection layer, the first passivation layer partially covers the light emitting unit, the first electrode and the second electrode, the first passivation layer includes a first opening, and the light emitting unit partially exposes from the first opening.

Referring to FIG. 10, patterning is performed to form the first passivation sublayer 52, and the required positions are exposed.

Referring to FIG. 11, patterning is performed to form the first electrode 30, the second electrode 40) and the bridge electrodes 150.

Referring to FIG. 12, patterning is performed to form the second passivation sublayer 53, and the required positions are exposed, to obtain the first passivation layer 50.

Step 803: forming a heat dissipating layer, wherein the heat dissipating layer covers the first passivation layer, and a part of the light emitting unit exposing from the first passivation laver.

In an alternative embodiment, after the step of forming the heat dissipating layer, the method further includes:
forming an optical-adjustment layer, wherein the optical-adjustment layer is provided with a second opening exposing the heat dissipating layer, and the heat dissipating layer includes a part embedded into the second opening; and
forming the heat dissipating end on the optical-adjustment layer, wherein the heat dissipating end covers an edge of the optical-adjustment layer close to the second opening, and the heat dissipating end is connected to the part of the heat dissipating layer that is embedded into the second opening.

Referring to FIGS. 13 to 16, in some embodiments, referring to FIG. 13, a heat-dissipating-material layer and an optical-adjustment-material layer are sequentially formed, and subsequently patterning is performed to form the heat dissipating layer 60 and the optical-adjustment layer 120, wherein the heat dissipating layer 60 includes a part embedded into the second opening 121. Referring to FIG. 14, the second passivation layer 160 is formed on the side wall of the via hole where the bonding-pad connector is required to be disposed. Referring to FIG. 15, the bonding-pad connector is formed. Referring to FIG. 16, the bonding-pad body is formed.

Subsequently, the heat dissipating end 140 may be formed on the optical-adjustment layer 120, wherein the heat dissipating end 140 is connected to the part of the heat dissipating layer 60 that is embedded into the second opening 121, to obtain the light emitting chip 1000 shown in FIG. 4.

In another alternative embodiment, after the step of forming the heat dissipating layer, the method further includes:
forming an optical-adjustment layer, wherein the optical-adjustment layer is provided with a second opening exposing the heat dissipating layer; and
forming a heat dissipating end on the heat dissipating layer exposing from the second opening.

Referring to FIG. 17, in some embodiments, the process of forming the heat dissipating layer 60, the optical-adjustment layer 120, the second passivation layer 160, the bonding-pad connector and the bonding-pad body is substantially the same as that according to the above embodiments, with the difference that the heat dissipating layer 60 does not include the part embedded into the second opening 121.

Subsequently, the heat dissipating end 140 may be formed on the heat dissipating layer 60 exposing from the second opening 121, wherein the heat dissipating end 140 is located in the second opening 121, to obtain the light emitting chip 1000 shown in FIG. 5.

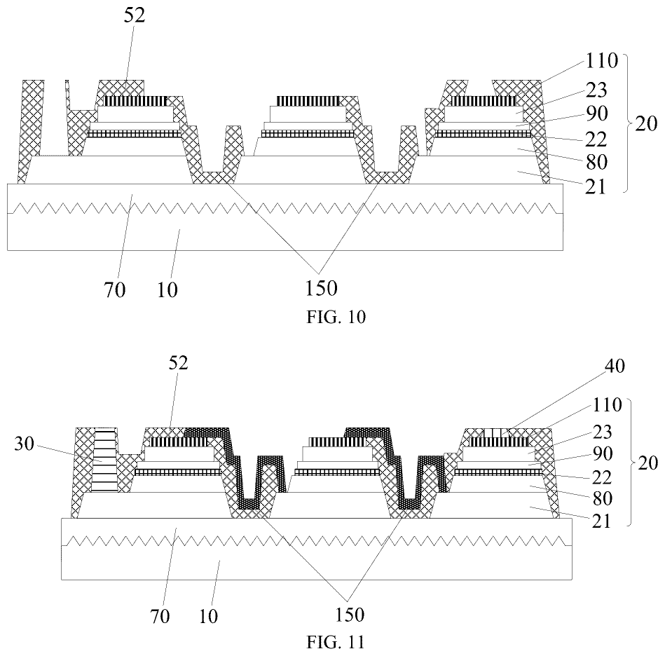

Furthermore, referring to FIG. 18, in some other embodiments, the process of forming the heat dissipating layer 60, the optical-adjustment layer 120, the second passivation layer 160, the bonding-pad connector and the bonding-pad body is substantially the same as that according to the above embodiments, with the difference that the optical-adjustment layer 120 does not include the opening 121. Subsequently, the heat dissipating end 140 is no formed, whereby the light emitting chip 1000 shown in FIG. 6 may be obtained.

Optionally, after the step of forming the heat dissipating end on the optical-adjustment layer, the method may further include the following steps: performing laser etching to the heat dissipating end 140, to form a fin structure on the heat dissipating end 140. That may increase the heat dissipating area of the heat dissipating end 140.

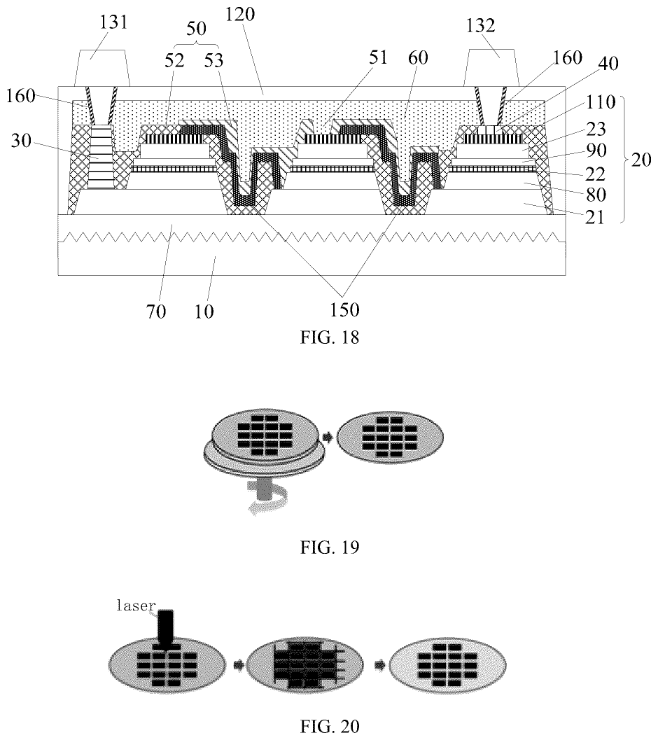

After the light emitting chip 1000 has been produced, referring to FIG. 19, the thickness of the sapphire substrate may be reduced by grinding, and, subsequently, referring to FIG. 20, the complete wafer may be cut into crystal particles by using laser. Subsequently, the crystal particles may undergo tests on photoelectric characteristics, classification by specification, and artificial visual inspection. Referring to FIG. 21, the tests on photoelectric characteristics refers to testing the photoelectric characteristics of each of the crystal particles by using a spot-measurement device. Referring to FIG. 22, the classification by specification refers to, according to the photoelectric parameters of the crystal particles, classifying the crystal particles into different specifications. Referring to FIG. 23, the artificial visual inspection refers to removing the crystal particles of a poor appearance artificially.

Furthermore, the producing method may further include other conventional steps, which is not particularly limited in the embodiments of the present disclosure.

In the embodiments of the present disclosure, the heat dissipating layer 60 may be formed inside the light emitting chip 1000, which increases the heat dissipating channels of the heat inside the light emitting chip 1000, thereby quickly discharging the temperature inside the light emitting chip 1000, to improve the heat-dissipation performance of the light emitting chip 1000, and reduce the overall temperature of the displaying device. Moreover, the heat dissipating layer 60 may serve as a high-strength packing layer inside the light emitting chip 1000, which may increase the mechanical strength of the light emitting chip 1000.

An embodiment of the present disclosure further discloses a light emitting apparatus, wherein the light emitting apparatus includes the light emitting chip 1000 stated above.

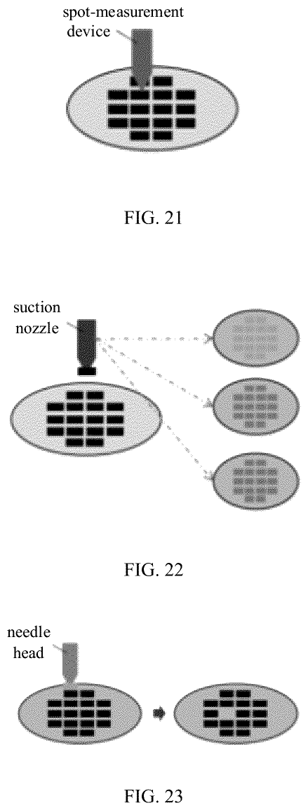

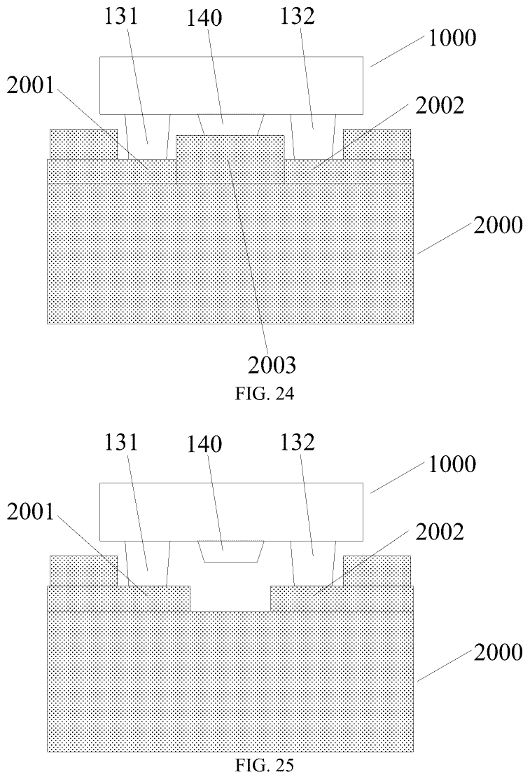

Referring to FIGS. 24 and 25, the light emitting apparatus further includes a driving base plate 2000, the driving base plate 2000 includes a first connecting end 2001 and a second connecting end 2002, the light emitting chip 1000 includes a first bonding pad 131 and a second bonding pad 132, the first bonding pad 131 is connected to the first connecting end 2001, and the second bonding pad 132 is connected to the second connecting end 2002. The first connecting end 2001 and the second connecting end 2002 may particularly be bonding pads.

The driving base plate 2000 may include two types, wherein one of the types is the driving base plate having a closed connecting end shown in FIG. 24, and the other type is the driving base plate having an opened connecting end shown in FIG. 25.

Regarding the driving base plate having a closed connecting end shown in FIG. 24, the driving base plate 2000 further includes a closing component 2003 located between the first connecting end 2001 and the second connecting end 2002, and the closing component 2003 is for closing a film layer exposing from between the first connecting end 2001 and the second connecting end 2002 on the driving base plate 2000.

By contrast, regarding the driving base plate having an opened connecting end shown in FIG. 25, there are not a closing component 2003 between the first connecting end 2001 and the second connecting end 2002.

Regarding the driving base plate having a closed connecting end shown in FIG. 24, when the light emitting chip 1000 includes the heat dissipating end 140, the heat dissipating end 140 may abut the closing component 2003.

Regarding the driving base plate having an opened connecting end shown in FIG. 25, when the light emitting chip 1000 includes the heat dissipating end 140, the heat dissipating end 140 may suitably have a certain distance from the film layer exposing from between the first connecting end 2001 and the second connecting end 2002.

Certainly, the light emitting chip 1000 not including the heat dissipating end 140 may also be provided with the driving base plate having a closed connecting end and the driving base plate having an opened connecting end, thereby forming the light emitting apparatus.

In the embodiments of the present disclosure, the heat dissipating layer 60 may be formed inside the light emitting chip 1000, which increases the heat dissipating channels of the heat inside the light emitting chip 1000, thereby quickly discharging the temperature inside the light emitting chip 1000, to improve the heat-dissipation performance of the light emitting chip 1000, and reduce the overall temperature of the displaying device. Meanwhile, the heat dissipating layer 60 may serve as a high-strength packing layer inside the light emitting chip 1000, thereby increasing the mechanical strength of the light emitting chip 1000.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it may be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “comprise” does not exclude elements or steps that are not listed in the claims. The word “a” or “an” preceding an element does not exclude the existing of a plurality of such elements. The present disclosure may be implemented by means of hardware comprising several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail with reference to the above embodiments, a person skilled in the art should understand that he may still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A light emitting chip, wherein the light emitting chip comprises:
a patterned substrate;
a light emitting unit, wherein the light emitting unit comprises an electron injection layer, a luminescent layer and a hole injection layer that are sequentially formed on the patterned substrate in stack;
a first electrode and a second electrode, wherein the first electrode is connected to the electron injection layer, and the second electrode is connected to the hole injection layer;
a first passivation layer, wherein the first passivation layer partially covers the light emitting unit, the first electrode and the second electrode, the first passivation layer comprises a first opening, and the light emitting unit partially exposes from the first opening; and
a heat dissipating layer, wherein the heat dissipating layer covers the first passivation layer, and a part of the light emitting unit exposing from the first passivation layer.

2. The light emitting chip according to claim 1, wherein the light emitting unit further comprises a current expanding layer formed on the hole injection layer, and the current expanding layer partially exposes from the first opening of the first passivation layer.

3. The light emitting chip according to claim 1, wherein the light emitting chip further comprises:
an optical-adjustment layer, wherein the optical-adjustment layer at least partially covers the heat dissipating layer; and
bonding pads, wherein the bonding pads comprise a first bonding pad and a second bonding pad, the first bonding pad is connected to the first electrode exposing from the first passivation layer by via holes in the optical-adjustment layer and the heat dissipating layer, the second bonding pad is connected to the second electrode exposing from the first passivation layer by via holes in the optical-adjustment layer and the heat dissipating layer, and the heat dissipating layer is insulative.

4. The light emitting chip according to claim 3, wherein the light emitting chip further comprises:
a heat dissipating end, wherein the heat dissipating end is disposed on the optical-adjustment layer, the optical-adjustment layer is provided with a second opening exposing the heat dissipating layer, and the heat dissipating end is connected to the heat dissipating layer by the second opening.

5. The light emitting chip according to claim 4, wherein an orthographic projection of the first opening on the patterned substrate and an orthographic projection of the heat dissipating end on the patterned substrate intersect or overlap.

6. The light emitting chip according to claim 4, wherein in a stacking direction of the light emitting chip, a height of a part of the heat dissipating end that exceeds the optical-adjustment layer is less than or equal to a height of a part of the bonding pads that exceeds the optical-adjustment layer.

7. The light emitting chip according to claim 4, wherein the heat dissipating end has a fin structure.

8. The light emitting chip according to claim 4, wherein the heat dissipating end is embedded into the second opening.

9. The light emitting chip according to claim 4, wherein the heat dissipating end covers an edge of the optical-adjustment layer close to the second opening.

10. The light emitting chip according to claim 4, wherein a material of the heat dissipating end is at least one of aluminium nitride and silicon carbide, and a material of the heat dissipating layer is at least one of aluminium nitride and silicon carbide.

11. The light emitting chip according to claim 4, wherein the light emitting chip comprises at least three light emitting units that are arranged in a target direction and are connected in series by bridge electrodes, the first electrode and the second electrode are individually connected to the light emitting units close to two ends of the light emitting chip, and an orthographic projection of the heat dissipating end on the patterned substrate and an orthographic projection on the patterned substrate of the light emitting unit between the light emitting units close to the two ends of the light emitting chip intersect or overlap.

12. The light emitting chip according to claim 11, wherein the first passivation layer comprises:
a patterned first passivation sublayer, wherein the first electrode is connected to the electron injection layer of the corresponding light emitting unit by a via hole in the first passivation sublayer, the second electrode is connected to the hole injection layer of the corresponding light emitting unit by the via hole in the first passivation sublayer, and each of the bridge electrodes is disposed on the first passivation sublayer, and connects two light emitting units by the via hole in the first passivation sublayer; and
a patterned second passivation sublayer, wherein the patterned second passivation sublayer covers the bridge electrodes, and the first opening is disposed in the second passivation sublayer.

13. The light emitting chip according to claim 3, wherein the light emitting chip further comprises:
a second passivation layer, wherein the second passivation layer is disposed on side walls of via holes of the optical-adjustment layer and the heat dissipating layer where the bonding pads are located.

14. The light emitting chip according to claim 1, wherein in a stacking direction of the light emitting chip, a minimum thickness of the heat dissipating layer is greater than or equal to 1.2 μm, and less than or equal to 4 micrometers.

15. A method for producing a light emitting chip, wherein the method comprises:
forming sequentially an electron injection layer, a luminescent layer and a hole injection layer in stack on a patterned substrate, to obtain a light emitting unit;
patterning to form a first passivation layer, a first electrode and a second electrode, wherein the first electrode is connected to the electron injection layer, the second electrode is connected to the hole injection layer, the first passivation layer partially covers the light emitting unit, the first electrode and the second electrode, the first passivation layer comprises a first opening, and the light emitting unit partially exposes from the first opening; and
forming a heat dissipating layer, wherein the heat dissipating layer covers the first passivation layer, and a part of the light emitting unit exposing from the first passivation layer.

16. The method according to claim 15, wherein after the step of forming the heat dissipating layer, the method further comprises:
forming an optical-adjustment layer, wherein the optical-adjustment layer is provided with a second opening exposing the heat dissipating layer; and
forming a heat dissipating end on the heat dissipating layer exposing from the second opening.

17. The method according to claim 15, wherein after the step of forming the heat dissipating layer, the method further comprises:
forming an optical-adjustment layer, wherein the optical-adjustment layer is provided with a second opening exposing the heat dissipating layer, and the heat dissipating layer comprises a part embedded into the second opening; and
forming the heat dissipating end on the optical-adjustment layer, wherein the heat dissipating end covers an edge of the optical-adjustment layer close to the second opening, and the heat dissipating end is connected to the part of the heat dissipating layer that is embedded into the second opening.

18. The method according to claim 16, wherein after the step of forming the heat dissipating end on the optical-adjustment layer, the method further comprises:
performing laser etching to the heat dissipating end, to form a fin structure on the heat dissipating end.

19. A light emitting apparatus, wherein the light emitting apparatus comprises the light emitting chip according to claim 1.

20. The light emitting apparatus according to claim 19, wherein the light emitting apparatus further comprises a driving base plate, the driving base plate comprises a first connecting end and a second connecting end, the light emitting chip comprises a first bonding pad and a second bonding pad, the first bonding pad is connected to the first connecting end, the second bonding pad is connected to the second connecting end, the driving base plate further comprises a closing component located between the first connecting end and the second connecting end, the closing component is for closing a film layer exposing from between the first connecting end and the second connecting end on the driving base plate, the light emitting chip comprises a heat dissipating end, and the heat dissipating end abuts the closing component.
